(19) United States
(12) Patent Application Publication
(10) Pub. No.: US 2025/0221152 A1
(43) Pub. Date: Jul. 3, 2025

(54) LIGHT-EMITTING DEVICE AND LIGHT-EMITTING DISPLAY DEVICE INCLUDING THE SAME

(71) Applicant: LG Display Co., Ltd., Seoul (KR)

(72) Inventors: Yu Jeong LEE, Paju-si (KR); Jun Su HA, Paju-si (KR); Eun Jung PARK, Paju-si (KR)

(73) Assignee: LG Display Co., Ltd., Seoul (KR)

(21) Appl. No.: 19/004,080

(22) Filed: Dec. 27, 2024

(30) Foreign Application Priority Data
Dec. 29, 2023 (KR) 10-2023-0197693

(51) Int. Cl. H10K 50/13; H10K 50/15; H10K 59/123; H10K 102/00

(52) U.S. Cl. CPC H10K 50/13; H10K 50/157; H10K 59/123; H10K 2102/351

(57) ABSTRACT

A light-emitting device can include a first electrode and a second electrode facing each other, and a red light-emitting layer provided between the first electrode and the second electrode. The light-emitting device can further include a hole injection layer, a first fluorescent material layer, and a first hole transport layer sequentially provided between the first electrode and the red light-emitting layer. The first fluorescent material layer has a band gap greater than a band gap of a red dopant contained in the red light-emitting layer. The light-emitting device and a light-emitting display device including the same reduce the driving voltage and improve lifespan of the device.

### CROSS-REFERENCE TO RELATED APPLICATION

This application claims priority to Korean Patent Application No. 10-2023-0197693, filed in the Republic of Korea on Dec. 29, 2023, the entire content of which is incorporated by reference in its entirety into the present application.

### BACKGROUND

### Technical Field

The disclosure relates to a light-emitting device having a modified structure to reduce driving voltage and improve lifespan, and a light-emitting display device including the same.

### Discussion of the Related Art

With the advent of the information society, displays for visually expressing electrical information signals have rapidly developed. In response to this, a variety of display devices with excellent performance such as slimness, low weight, and low power consumption are being developed.

Among these devices, a light-emitting display device that does not require a separate light source to realize compactness and clear color and has a light-emitting device in a display panel has been considered as a competitive application.

The light-emitting device can include an anode and a cathode facing each other as electrodes, a light-emitting layer between the anode and the cathode, and a common layer for transferring holes and electrons to the light-emitting layer.

Meanwhile, light-emitting devices emit light upon a recombination of holes with electrons within the light-emitting layer. The recombination between the holes and the electrons causes formation of excitons. When the energy of the excitons drops from the excited state to the ground state, light is emitted. The difference in speed between the holes and the electrons occurs, and holes accumulate at the interface of the common layer, which can cause deterioration in efficiency and lifespan.

### SUMMARY OF THE DISCLOSURE

Accordingly, the disclosure is directed to a light-emitting device and a light-emitting display device that substantially obviate one or more problems due to the limitations and disadvantages of the related art.

It is an object of the present disclosure to provide a light-emitting device and a light-emitting display device that further include a material layer between the first electrode (anode) and the light-emitting layer to prevent reduction in efficiency and increase lifespan. The fluorescent material layer has excellent hole transport properties and thus prevents charges trapping at the interface between the light-emitting layer and the common layer, thereby reducing driving voltage and improving lifespan.

Additional advantages, objects, and features of the disclosure will be set forth in part in the description which follows and in part will become apparent to those having ordinary skill in the art upon examination of the following, or can be learned from practice of the disclosure. The objectives and other advantages of the disclosure can be realized and attained by the structure particularly pointed out in the written description and claims hereof as well as the appended drawings.

A light-emitting device according to an embodiment of the present disclosure includes a first electrode and a second electrode facing each other, a red light-emitting layer provided between the first electrode and the second electrode, and a hole injection layer, a first fluorescent material layer, and a first hole transport layer sequentially provided between the first electrode and the red light-emitting layer, wherein the first fluorescent material layer has a band gap greater than a band gap of a red dopant contained in the red light-emitting layer.

It is to be understood that both the foregoing general description and the following detailed description of the disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view illustrating a light-emitting device according to a first embodiment of the present disclosure.

FIG. 2 shows an energy band diagram of region A of FIG. 1 and an adjacent hole injection layer.

FIG. 3 shows comparison in the energy band gap between a red dopant and a fluorescent material contained in a fluorescent material layer.

FIG. 4 shows a triplet energy level of each layer and a light emission mechanism of a red light-emitting layer in region A.

FIG. 5 is a graph showing the PL spectra of Experimental Examples 2 and 3.

FIG. 6 shows the triplet energy levels of the hole transport layer, the fluorescent material layer, and the red light-emitting layer and the light emission mechanism of the red light-emitting layer in Experimental Example 4.

FIG. 7 is a graph showing the PL spectra of Experimental Examples 2 and 4.

FIG. 8 is a cross-sectional view illustrating a light-emitting device according to a second embodiment of the present disclosure.

FIG. 9 is a cross-sectional view illustrating a light-emitting device according to a third embodiment of the present disclosure.

FIG. 10 is a cross-sectional view illustrating a light-emitting device according to a fourth embodiment of the present disclosure.

FIG. 11 is a cross-sectional view illustrating a light-emitting display device according to an embodiment of the present disclosure.

### DETAILED DESCRIPTION OF THE EMBODIMENTS

Reference will now be made in detail to various embodiments of the disclosure, examples of which are illustrated in the accompanying drawings.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected: consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details, instances, known methods, procedures, components, and circuits have not been described in detail so as not to unnecessarily obscure aspects of the present disclosure. All the components of the inorganic light emitting display device according to all embodiments of the present disclosure are operatively coupled and configured. Further, the term “can” fully encompasses all the meanings and coverages of the term “may.”

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

In the following description of the present disclosure, the Lowest Unoccupied Molecular Orbital (LUMO) energy level and the Highest Occupied Molecular Orbital (HOMO) energy level of a layer mean the LUMO energy level and the HOMO energy level of a material constituting a major weight ratio of the corresponding layer, unless they refer to the LUMO energy level and the HOMO energy level of a dopant material doping the corresponding layer.

In the following description of the present disclosure, a HOMO energy level can be obtained by measuring a voltage corresponding to a first peak at which electrons are emitted from a material through cyclic voltammetry (CV) for the material to be measured, compared to a reference material whose HOMO energy level is known. Herein, the electron that first comes out of the material is the weakest bound electron, e.g., the outermost electron, and is in the state of the HOMO energy level. As an example, the HOMO energy levels and the LUMO energy levels in the Tables of present disclosure, are compared to a HOMO energy level and a LUMO energy level of NPD (N,N′-Di(1-naphthyl)-N,N′-diphenyl-(1,1′-biphenyl)-4,4′-diamine). NPD has a HOMO energy level −5.5 eV and a LUMO energy level of −2.4 ev. But embodiments of the present disclosure are not limited thereto.

In the present disclosure, a band gap energy (Eg) can be measured by ultraviolet-visible spectrometry (UVvis).

In the present disclosure, a LUMO energy level can be obtained by subtracting the band gap energy from the HOMO energy level measured above.

In the present disclosure, the HOMO energy level and the LUMO energy level are measured values below the vacuum level of 0 eV, thus they are negative values. When the HOMO energy levels or LUMO energy levels of materials are compared, that the HOMO energy level (or the LUMO energy level) of a first material is larger than the HOMO energy level (or the LUMO energy level) of a second material in an energy band diagram means that the HOMO energy level (or the LUMO energy level) of the second material is larger than the HOMO energy level (or the LUMO energy level) of the first material in absolute values. When the HOMO energy levels or LUMO energy levels of materials are compared, that the HOMO energy level (or the LUMO energy level) of a first material is lower than the HOMO energy level (or the LUMO energy level) of a second material in an energy band diagram means that the HOMO energy level (or the LUMO energy level) of the first material is larger than the HOMO energy level (or the LUMO energy level) of the second material in an absolute value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. Further, for convenience of description, a scale in which elements is illustrated in the accompanying drawings can differ from an actual scale. Thus, the illustrated elements are not limited to the specific scale in which they are illustrated in the drawings.

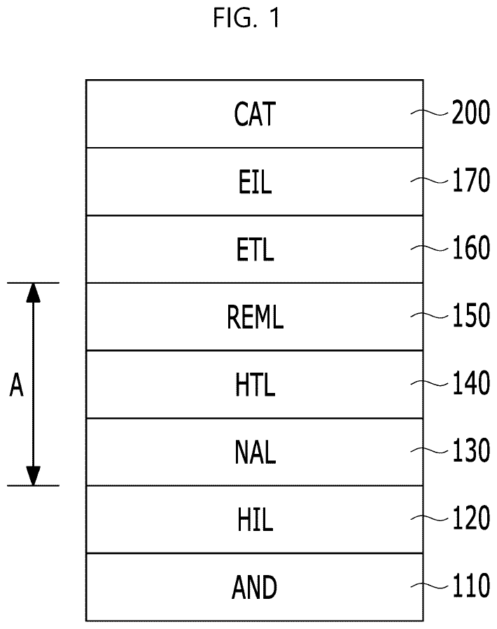

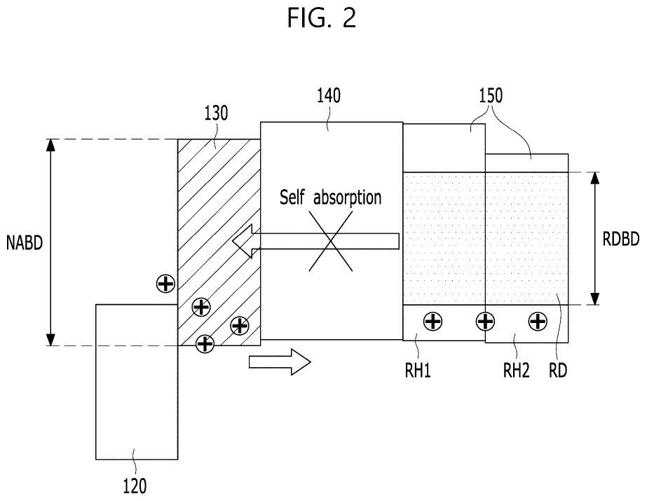

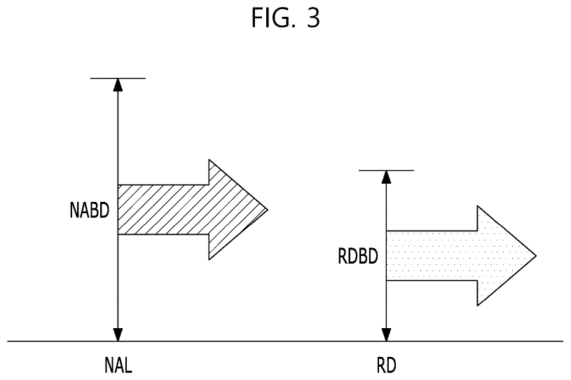

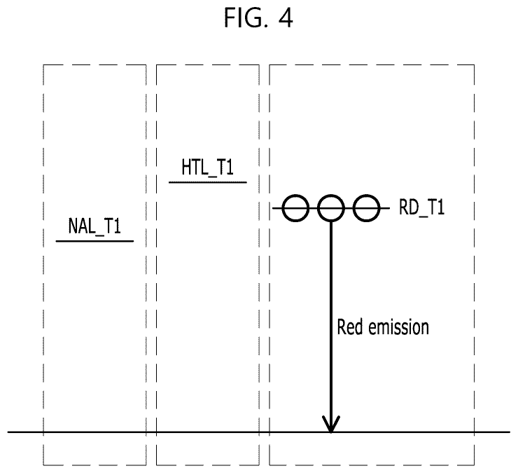

FIG. 1 is a cross-sectional view illustrating a light-emitting device according to a first embodiment of the present disclosure, and FIG. 2 shows an energy band diagram of region A of FIG. 1 and an adjacent hole injection layer. FIG. 3 shows comparison in the energy band gap between a red dopant and a fluorescent material contained in a fluorescent material layer. FIG. 4 shows a triplet energy level of each layer and a light emission mechanism of a red light-emitting layer in region A.

As shown in FIG. 1, the light-emitting device according to an embodiment of the present disclosure includes a first electrode 110 and a second electrode 200 facing each other, a red light-emitting layer 150 provided between the first electrode and the second electrode, and a hole injection layer 120, a fluorescent material layer 130, and a hole transport layer 140 sequentially provided between the first electrode 110 and the red light-emitting layer 150. In addition, the light-emitting device can further include an electron transport layer 160 and an electron injection layer 170 between the red light-emitting layer 150 and the second electrode 200.

One of the first electrode 110 and the second electrode 200 can be an anode, and the other can be a cathode.

One of the first electrode 110 and the second electrode 200 can be a reflective electrode, and the other can be a transparent electrode or a semi-transparent electrode.

In the light-emitting display device according to an embodiment of the present disclosure, the first electrode 110 is connected to a thin film transistor provided on the substrate to selectively receive a signal supplied to each sub-pixel, and the second electrode 200 is common in the sub-pixels to receive a common voltage.

The hole injection layer 120 can be formed of a hole injection material containing a single organic or inorganic compound, or can be formed of a hole transport material doped with a p-type dopant. The hole injection layer 120 has the first interface to supply holes from the first electrode 110 into the intermediate layer (material between the first and second electrodes) and functions to reduce the barrier against injection of holes from the first electrode 110.

As shown in FIG. 2, the hole injection layer 120 is formed of a material with low LUMO and HOMO, reduces the barrier against injection of holes, and has dipole properties. In this case, the inner portion of the hole injection layer 120 adjacent to the first electrode 110 is negatively charged, a portion of the hole injection layer contacting the fluorescent material layer 130 is positively charged, the hole injection layer 120 attract holes from the first electrode 110, and holes are easily injected from the first electrode 110 at a level corresponding to the LUMO energy level of the hole injection layer 120.

The hole injection layer 120 can have a LUMO energy level similar to the work function.

For example, the hole injection layer 120 can include tetrafluoro-tetracyanoquinodimethane (F4TCNQ: 7,7,8,8-tetracyano-2,3,5,6-tetrafluoroquinodimethane), fluorine-substituted 3,4,9,10-perylen tetracarboxylic dianhydride (PTCDA), cyano-substituted PTCDA, 1,4,5,8-naphthalene tetracarboxylic dianhydride (NTCDA), hexanitrile hexaazatriphenylene (HAT), or hexaazatriphenylene hexacarbonitrile (HAT-CN), or a derivative thereof.

Here, the fluorescent layer 130 is photoluminescent (PL) at a shorter wavelength than red, and can be, for example, a green fluorescent dopant or a blue fluorescent dopant. Alternatively, the fluorescent material layer 130 can be a fluorescent dopant capable of emitting ultraviolet wavelengths. The fluorescent material layer 130 is not affected by the light emission of the red light-emitting layer 150. As shown in FIGS. 2 and 3, the bandgap NABD of the fluorescent material layer 130 falls within a range larger than the bandgap RDBD of the red dopant RDBD, so light emission caused by the energy change of the excitons in the red dopant RD does not result in a change in an energy that causes the fluorescent material layer 130 to emit light.

In addition, the fluorescent material layer 130 contains a fluorescent material, but acts as a non-absorption layer NAL because it does not absorb light emitted from the red light-emitting layer 150.

For example, the fluorescent material layer 130 includes, as a whole or as a main component, a fluorescent dopant emitting light at a shorter wavelength than a red dopant. The fluorescent material layer 130 can include an organic hole-transporting organic component in addition to the fluorescent dopant. The fluorescent dopant contained in the fluorescent material layer 130 is, for example, an organic material containing anthracene as a core, and has a triplet energy level lower than the triplet energy level of the red dopant. Accordingly, even if some excitons or electrons are introduced from the red light-emitting layer 150, the excitons are annihilated by energy radiation without light emission at a low triplet level, thereby preventing excitons from accumulating at the interface of the hole transport layer or within the hole transport layer, and improving the lifespan of the light-emitting device.

Meanwhile, the fluorescent material constituting the fluorescent material layer 130 contains an anthracene substituted with an aromatic amine group as the core and thus is capable of transporting holes well between the first electrode 110 and the red light-emitting layer 150.

For example, the fluorescent material layer 130 can include a material represented by Formulas 1 to 3. Here, the term “Formula” can include compound(s), equation(s), chemical structure(s), or the like, or any combination thereof. Formulas 1 to 3 are provided only as examples and can be selected from any materials that have a band gap energy greater than that of the red dopant RD, maintain non-emission characteristics when the red light-emitting layer 150 emits light, and is capable of transporting holes well to the light-emitting layer 150.

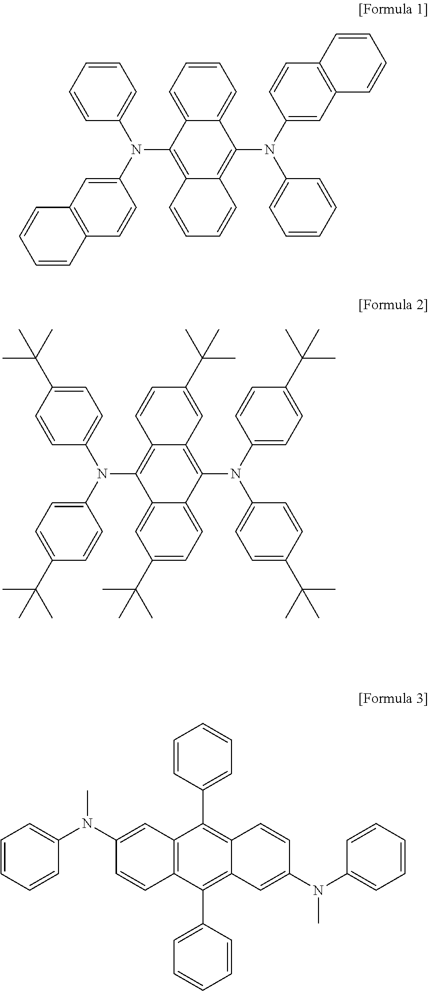 [SMILES: c1ccc(N(c2ccc3ccccc3c2)c2c3ccccc3c(N(c3ccccc3)c3ccc4ccccc4c3)c3ccccc23)cc1 ; CC(C)(C)c1ccc(N(c2ccc(C(C)(C)C)cc2)c2c3ccc(C(C)(C)C)cc3c(N(c3ccc(C(C)(C)C)cc3)c3ccc(C(C)(C)C)cc3)c3ccc(C(C)(C)C)cc23)cc1 ; CN(c1ccccc1)c1ccc2c(-c3ccccc3)c3cc(N(C)c4ccccc4)ccc3c(-c3ccccc3)c2c1]

In addition, holes injected through the hole injection layer 120 are sequentially transferred to the red light-emitting layer 150 through the HOMO energy levels of the fluorescent material layer 130, the hole transport layer 140, and the red light-emitting layer 150.

For example, the hole transport layer 140 can be formed of an amine-based hole transport material. Holes injected through the hole injection layer 110 pass through the hole transport layer 140 and are transferred to the red light-emitting layer 150.

The hole transport layer 140 can include a material that has the best hole transport property between the first and second electrodes 110 and 200.

For example, the material constituting the hole transport layer 140 is NPB (N,N′-bis-(1-naphthalenyl)-N,N′-bis-phenyl-(1,1′-biphenyl)-4,4′-diamine) (also called NPD (N,N′-bis(naphthalene-1-yl)-N,N′-bis(phenyl)benzidine)), TPD (N,N′-bis-(3-methylphenyl)-N,N′-bis-phenyl)-benzidine), S-TAD, or MTDATA (4,4′,4″-tis (N-3-methylphenyl-N-phenyl-amino)-triphenylamine), or a derivative thereof. Meanwhile, in the light-emitting device of the present disclosure, the hole transport material in the hole transport layer is not limited to those described above and can be any material that has hole transport property and a triplet energy level higher than the triplet energy level of the red dopant of the red light-emitting layer.

The red light-emitting layer 150 includes red hosts RH1 and RH2 and a red dopant RD. The red host RH can include a single host or can include two or more types of hosts RH1 and RH2 with different transport properties.

When the red host includes a hole-transporting first host RH1 and an electron-transporting second host RH2, the red dopant RD has a small energy band gap RDBD. In this case, the red host has a HOMO energy level higher than the HOMO energy level of the first host RH1 and a LUMO energy level lower than the LUMO energy level of the second host RH2, thus facilitating energy transfer of the first and second hosts RH1 and RH2 to the red dopant RD and exciton generation by recombination of holes and electrons in the red dopant.

Meanwhile, the red dopant RD of the red light-emitting layer 150 of the light-emitting device of the present disclosure can be a phosphorescent dopant. The emission peak of the light emitted from the red dopant RD is observed at about 600 nm to about 650 nm, and the PL emission peak of the fluorescent dopant constituting the fluorescent material layer 120 is observed at a lower level of the ultraviolet wavelength to 590 nm. Here, even if the red light-emitting layer 150 emits light in a light-emitting device including the red light-emitting layer 150, as shown in FIG. 3, the light emission from the red light-emitting layer 150 does not reach the energy band gap sufficient to cause fluorescence (PL) in the fluorescent material layer 120 and thus the fluorescent material layer 120 does not emit light.

For example, the electron transport layer 160 can be formed of an anthracene-based electron transport material. The electron transport layer 160 transfers electrons from the electron injection layer 170 to the red light-emitting layer 150.

The electron injection layer 170 contacts the second electrode 200 and serves to reduce the barrier against injection of electrons from the second electrode 200 into the intermediate layer. The electron injection layer 170 can include a halogen atom bonded to an alkali metal or alkaline earth metal and/or an electron-transporting organic material.

Referring to FIG. 4, the light emission mechanism of the light-emitting device of the present disclosure will be described.

A phosphorescent device has a long triplet exciton diffusion distance of about 100 nm because the triplet excitons retain in the excited state for a long time. However, it is necessary to confine the triplet excitons within the light-emitting layer as much as possible because light can be emitted when the excitons fall to the ground state after formation of excitons due to recombination of holes and electrons in the dopant within the light-emitting layer.

Therefore, the light-emitting device of the present disclosure prevents diffusion of excitons from the hole transport layer HTL to the light-emitting layer REML because the triplet energy level (HTL_T1) of the hole transport material constituting the hole transport layer 140 is designed to be higher than the triplet energy level (RD_T1) of the red dopant RD (HTL_T1>RD_T1).

Based on the same mechanism, the triplet energy level (ETL_T1) of the electron transport material constituting the electron transport layer (160 in FIG. 1) is higher than the triplet energy level (RD_T1) of the red dopant RD, thereby preventing the diffusion of excitons from the red light-emitting layer REML to adjacent layers, but the light-emitting device of the present disclosure is not limited thereto. In the light-emitting device of the present disclosure, excitons in the red light-emitting layer REML 150 are concentrated toward the hole transport layer 130, so exciton control is possible at the same level as in FIG. 4, although the triplet energy level of the material for the electron transport layer 160 is equal to or lower than the triplet energy level (RD_T1) of the red dopant RD.

Meanwhile, in the light-emitting device of the present disclosure, as shown in FIG. 4, the triplet energy level (NAL T1) of the fluorescent material layer 120 can be designed to be lower than the triplet energy level (HTL_T1) of the adjacent hole transport layer 130. In this case, the fluorescent material layer 120 is spaced apart from the red light-emitting layer 150 with the hole transport layer 130 having a large triplet energy level (HTL_T1) interposed therebetween. Therefore, it is possible to primarily prevent the phenomenon in which triplet excitons are transferred from the red light-emitting layer REML 150 to the hole transport layer HTL 130. Although some triplet excitons are transferred to the fluorescent material layer NAL 120, the triplet excitons are annihilated at the low triplet energy level of the fluorescent material layer NAL 120 and do not contribute to the luminous efficiency within the fluorescent material layer NAL 120. Therefore, the light-emitting device of the present disclosure maintains the purity of red light emission of the red light-emitting layer 150, prevents quenching within the red light-emitting layer 150 by annihilating the triplet excitons that move during long-term excitation of phosphorescence, and prevents a decrease in lifespan due to trapping of excitons or electrons in the red light-emitting layer 150 and adjacent layers.

Meanwhile, in the following, the significance of the light-emitting device of the present disclosure will be determined through experiments.

In the following experiment, the light-emitting device of the present disclosure described in FIGS. 1 to 4 is defined as the structure of Experimental Example (EX2), and the light-emitting device that does not include a fluorescent material layer between the hole injection layer and the hole transport layer is defined as the structure of Experimental Example 1 (EX1). For example, Experimental Example (EX1) has the same structure as that of FIG. 1 except that it does not include a fluorescent material layer.

### Experiment 1

In Experiment 1, the light-emitting device of Experimental Example 1 (EX1) is manufactured as follows.

ITO is deposited on a substrate to formed a first electrode AND.

A hole transport material is doped with 10 wt % of a p-type dopant to a thickness of 100 Å on the first electrode AND to form a hole injection layer HIL.

Next, a hole transport material is deposited to a thickness of 100 Å on the hole injection layer HIL to form a hole transport layer HTL. The hole transport material can have a triplet energy level (HTL_T1) of about 2.2 eV.

Next, a hole-transporting first host RH1 and an electron-transporting second host RH2 as hosts are doped with 1 wt % to 10 wt % of a red dopant RD on the hole transport layer HTL, to a thickness of 150 Å to form a light-emitting layer REML.

Next, an anthracene-based material is deposited to a thickness of 150 Å on the light-emitting layer REML to form an electron transport layer ETL.

Next, LiF is deposited to a thickness of 10 Å on the electron transport layer ETL to form an electron injection layer.

Next, aluminum is deposited on the electron injection layer EIL to form a second electrode CAT.

In Experimental Example 2 (EX2), a hole injection layer HIL is formed, any one fluorescent material of Formulas 1 to 3 is deposited to a thickness of 30 Å to form a fluorescent material layer NAL 130, and then a hole transport layer HTL with a thickness of 70 Å is formed. Then, in the same manner as in Experimental Example 1 (EX1), a red light-emitting layer REML, an electron transport layer ETL, an electron injection layer EIL and a second electrode CAT are sequentially formed.

Experimental Example 3 (EX3) has the same structure as Experimental Example 2 (EX2), except that the hole injection layer HIL is formed, any one fluorescent material of Formulas 1 to 3 is deposited to a thickness of 50 Å to form a fluorescent material layer NAL 130, and a hole transport layer HTL is then formed to a thickness of 50 Å.

In Experimental Example 2 (EX2) and Experimental Example 3 (EX3), a total thickness of the fluorescent material layer NAL and the hole transport layer HTL is the same as the thickness, 100 Å of the hole transport layer of Experimental Example 1 (EX1).

In the experiments, IVL characteristics are measured at a current density of 10 mA/cm².

T95 lifespan refers to an elapsed time until the luminance reaches 95% of the initial luminance, under acceleration conditions of a driving temperature of 40° C. and a current density of 40 mA/cm².

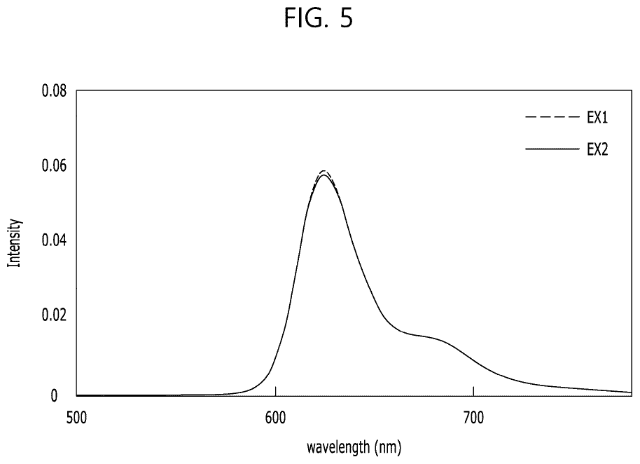

FIG. 5 is a graph showing the PL spectra of Experimental Examples 2 and 3.

TABLE 1

| | | IVL@10 mA/cm² | | | |
|---|---|---|---|---|---|
| | | Driving | | | |
| | NAL | voltage | EQE | R | Lifespan |
| Item | [thickness(Å)] | (ΔV)[V] | (%) | (%) | T95(%) |
| EX1 | 0 | 0 | 100 | 100 | 100 |
| EX2 | 30 | −0.10 | 99.8 | 99.9 | 194.9 |
| EX3 | 50 | −0.25 | 96.1 | 96.6 | 205.3 |

As can be seen from Table 1 and FIG. 5, the color purity of red is similar in Experimental Examples 1, 2 and 3 (EX1, EX2, EX3).

In addition, it can be seen that, compared to Experimental Example 1 (EX1), Experimental Examples 2 and 3 (E×2 and E×3) exhibit a decrease in the driving voltage as the thickness of the fluorescent material layer between the hole injection layer and the hole transport layer increases.

It can be seen that, compared to Experimental Example 1 (EX1), Experimental Examples 2 and 3 (E×2 and E×3) exhibit an increase in lifespan of T95 as the thickness of the fluorescent material layer between the hole injection layer and the hole transport layer increases. In particular, when comparing Experimental Example 1 (EX1) with Experimental Example 2 (EX2), the lifespan of the fluorescent material layer NAL of Experimental Example 2 (EX2) is approximately twice that of Experimental Example 1 (EX1) even if the fluorescent material layer NAL is provided between the hole injection layer and the hole transport layer.

Experimental Example 2 (EX2) and Experimental Example 3 (EX3) according to the structure of the light-emitting device of the present disclosure include a fluorescent material layer NAL 130 formed using a fluorescent dopant material that has excellent hole transport properties to increase hole transport from the first electrode 110 to the red light-emitting layer 150 and has a large energy band gap that does not absorb light emitted from the red light-emitting layer 150, between the hole injection layer HIL 110 and the hole transport layer HTL 140.

The light-emitting device of the present disclosure has a configuration in which the emitted red light is not absorbed in the fluorescent material layer NAL 130, thereby providing effects of maintaining the color purity of emitted red light from the red light-emitting layer REML 150, controlling abnormal light emission in other areas, reducing the driving voltage, and greatly increasing lifespan.

In addition, the light-emitting device of the present disclosure prevents holes from being trapped at the interface of the hole transport layer 140 contacting the red light-emitting layer REML 150, causes annihilation of the excitons moving from the red light-emitting layer REML 150 toward the first electrode 110 in the fluorescent material layer, and thus prevents deterioration caused by accumulation of excitons in the red light-emitting layer REML 150 and the hole transport layer

HTL 140 and a corresponding decrease in lifespan. When the fluorescent material layer is not provided, as in Experimental Example 1 (EX1), although the triplet energy level (HTL_T1) of the hole transport layer HTL is higher than the triplet energy level (RD_T1) of the red dopant in the red light-emitting layer REML, if the difference is as small as 0.1 eV ((HTL_T1−RD_T1)≤ 0.1 eV), problems in which some triplet excitons escape from the red light-emitting layer REML, travel to the first electrode 110, and triplet excitons diffuse into the hole transport layer HTL can occur. In this case, problems such as reduced luminous efficacy and lifespan can occur.

Hereinafter, Experimental Example 4 in which the fluorescent material layer is in direct contact with the red light-emitting layer will be reviewed to determine the significance of the light-emitting device of the present disclosure.

Compared to Experimental Example 1, the light-emitting device according to Experimental Example 4 (EX4) has a structure including a fluorescent material layer NAL between the hole transport layer HTL and the red light-emitting layer REML.

Specifically, in Experimental Example 4 (EX4), a hole injection layer HIL is formed, a hole transport material is formed to a thickness of 70 Å to form a hole transport layer HTL, a fluorescent material represented by any one of Formulas 1 to 3 is deposited to a thickness of 30 Å to form a fluorescent material layer NAL, and a red light-emitting layer REML, an electron transport layer ETL, an electron injection layer EIL, and a second electrode CAT are formed on the fluorescent material layer NAL in the same manner as in Experimental Example 1 (EX1).

The total thickness of the hole transport layer HTL and the fluorescent material layer NAL in Experimental Example 4 (EX4) is the same as the thickness, 100 Å of the hole transport layer HTL in Experimental Example 1 (EX1).

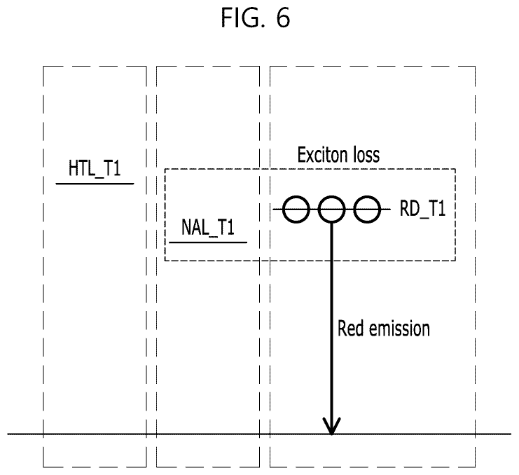

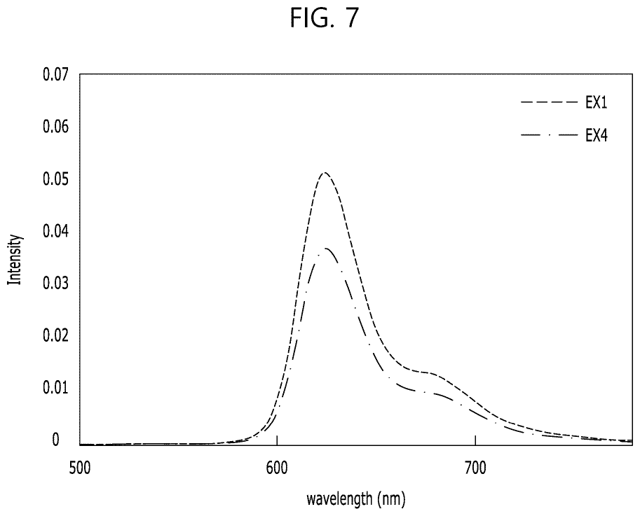

FIG. 6 shows the triplet energy levels of the hole transport layer, the fluorescent material layer, and the red light-emitting layer and the light emission mechanism of the red light-emitting layer in Experimental Example 4. FIG. 7 is a graph showing the PL spectra of Experimental Examples 1 to 4.

TABLE 2

| | Structure | | | | |
|---|---|---|---|---|---|
| | between | | | | |
| | the first | | | | |
| | electrode | | | | |
| | and the | | | | |
| | red-light | | | | |
| | emitting | IVL@10 mA/cm² | | | |
| | layer/NAL | Driving | | | |
| | thickness | voltage | | R | Lifespan |
| Item | (Å) | (ΔV)[V] | EQE(%) | (%) | T95(%) |
| EX1 | HIL/HTL | 0 | 100 | 100 | 100 |
| | 0 | | | | |
| EX2 | HIL/NAL/HTL | −0.10 | 99.8 | 99.9 | 194.9 |
| | 30 | | | | |
| EX4 | HIL/HTL/NAL | −0.15 | 74.5 | 72.9 | 334.2 |
| | 30 | | | | |

As shown in FIG. 6, in the light-emitting device according to Experimental Example 4 ((EX4) of the present disclosure, the triplet energy level (NAL_T1) of the fluorescent material layer NAL is lower than the triplet energy level (RD_T1) of the red dopant RD, so the triplet excitons generated in the red light-emitting layer REML readily diffuse into the adjacent fluorescent material layer NAL, and cannot be used for the emission of triplet excitons in the fluorescent material layer NAL and are annihilated, and the decrease in red color purity is severe, as shown in Table 2 and FIG. 7.

In Table 2, compared to Experimental Example 1 (EX1), Experimental Example 4 (EX4) has the advantages of low driving voltage and improved lifespan by preventing exciton accumulation at the interface of the hole transport layer, but has a problem of difficulty in expressing pure color as a red light-emitting device due to poor red color purity.

For example, the light-emitting device of the present disclosure has a hole transport layer HTL having a triplet energy level higher than the triplet energy level of the red dopant RD (RD_T1<HTL_T1) immediately adjacent to the red light-emitting layer, as in Experimental Examples 2 and 3 (EX2, EX3), to form a primary barrier for triplet excitons to escape from the red light-emitting layer REML, to cause quenching of some triplet excitons escaping from the red light-emitting layer REML by a fluorescent dopant material having an energy band gap (<NABD) greater than the energy band gap RDBD in a fluorescent material layer NAL spaced from the red light-emitting layer REML with the hole transport layer HTL interposed therebetween at the time of red emission, to prevent exciton accumulation at any interface of common layers between the first electrode 110 and the red light-emitting layer REML 150, to maintain red purity, and to realize improved lifespan and reduced driving voltage.

Hereinafter, a light-emitting device according to another embodiment of the present disclosure will be described.

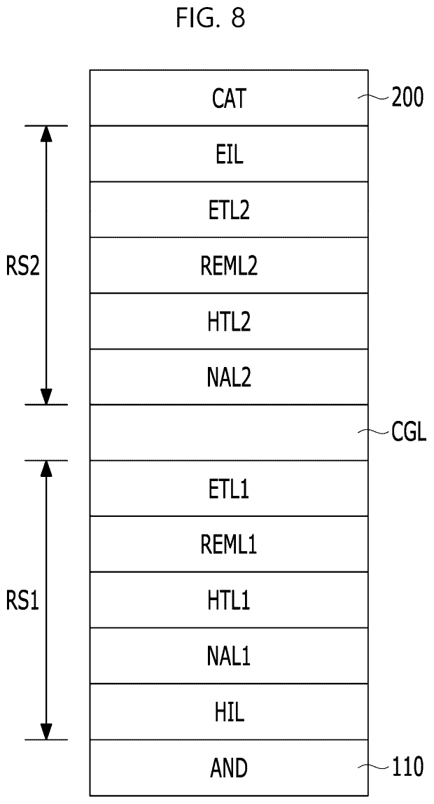

FIG. 8 is a cross-sectional view illustrating a light-emitting device according to a second embodiment of the present disclosure.

As shown in FIG. 8, the light-emitting device according to the second embodiment of the present disclosure is provided with a plurality of stacks that emit red light.

In the illustrated example, as shown in FIG. 8, a first red stack RS1, a charge generation layer CGL, and a second red stack RS2 are sequentially provided between the first electrode 110 and the second electrode 200.

The first red stack RS1 includes a hole injection layer HIL, a first fluorescent material layer NAL1, a first hole transport layer HTL1, a first red light-emitting layer REML1, and a first electron transport layer ETL1.

The charge generation layer CGL can be provided as a single layer by doping a single host with an n-type dopant or a p-type dopant, or as a stack including an n-type charge generation layer and a p-type charge generation layer by doping different hosts with different dopants, respectively.

The second red stack RS2 includes a second fluorescent material layer NAL2, a second hole transport layer HTL2, a second red light-emitting layer REML2, and a second electron transport layer ETL2.

Here, the first red stack RS1 has the same configuration from the hole injection layer HIL to the electron transport layer of FIG. 1, as above.

The second red stack RS2 includes a second fluorescent material layer NAL2 contacting the charge generation layer CGL, and the configuration from the second fluorescent material layer NAL2 to the electron injection layer EIL is the same as the light-emitting layer of FIG. 1. When the charge generation layer

CGL has a two-layer structure of an n-type charge generation layer and a p-type charge generation layer, the second fluorescent material layer NAL can contact the p-type charge generation layer.

The light-emitting device according to FIG. 8 can improve red efficiency in a sub-pixel that emits red light compared to a single-stack light-emitting device.

The first and second red light-emitting layers REML1 and REML2 can include the same red host and the same red dopant. In some cases, in the first and second red light-emitting layers REML1 and REML2, at least one of the red host and the red dopant can be different, the thickness of the first and second red light-emitting layers can be different, or the content of the red host or red dopant thereof can be different, thereby controlling light emission characteristics depending on color purity, color temperature, optical distance and viewing angle.

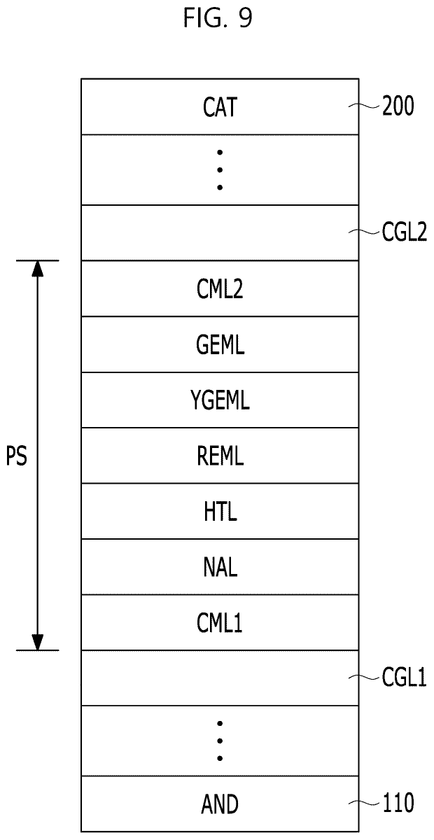

FIG. 9 is a cross-sectional view illustrating a light-emitting device according to a third embodiment of the present disclosure.

As shown in FIG. 9, the light-emitting device according to the third embodiment of the present disclosure includes a plurality of stacks including a phosphorescent stack PS including a red light-emitting layer REML between the first electrode AND and the second electrode CAT.

The phosphorescent stack PS can be distinguished from other stacks through the charge generation layers (CGL1 and CGL2). The other stack can be provided either below or above the phosphorescent stack PS, or can be provided both below and above the phosphorescent stack PS.

The phosphorescent stack PS includes, for example, a first common layer CML1, a fluorescent material layer NAL, a hole transport layer HTL, a red light-emitting layer REML, a yellow-green light-emitting layer YGREML, a green light-emitting layer GEML, and a second common layer CML2.

The first common layer CML1 can include a hole injection and/or a hole transport material. In some cases, the first common layer CML1 can be omitted and the charge generation layer CGL and the fluorescent material layer NAL can directly contact each other.

The second common layer CML2 can include an electron transport material and/or an electron injection material.

The example shown in FIG. 9 shows that the phosphorescent stack PS is provided with a plurality of phosphorescent light-emitting layers, including a red light-emitting layer, a yellow-green light-emitting layer, and a green light-emitting layer, but the light-emitting device of the present disclosure is not limited thereto. The phosphorescent stack PS can include only a red light-emitting layer and a green light-emitting layer, or can have a configuration in which at least one of a red light-emitting layer, a yellow-green light-emitting layer, or a green light-emitting layer includes two or more layers.

The phosphorescent stack PS is formed using a fluorescent material layer NAL having an energy band gap larger than that of the red dopant between the red light-emitting layer REML and the charge generation layer CGL, so that the light emission of the red light-emitting layer does not cause light emission in the fluorescent material layer NAL, and does not affect the phosphorescent properties. The red light-emitting layer REML can share excitons with the yellow-green light-emitting layer YGEML and the green light-emitting layer GEML configured in this order in the phosphorescent stack PS, triplet excitons not used for emission in the green light-emitting layer GEML can be used for light emission in the yellow-green light-emitting layer YGEML and the red light-emitting layer REML, and triplet excitons not used for emission in the yellow-green light-emitting layer YGEML can be used for light emission in the red light-emitting layer REML.

In the light-emitting device of the present disclosure, as shown in FIG. 9, a large amount of excitons are transferred to the red light-emitting layer REML due to the plurality of phosphorescent light-emitting layers, so even if some excitons move from the red light-emitting layer REML toward the charge generation layer CGL1, excitons are annihilated in the fluorescent material layer NAL containing a fluorescent material with a small band gap, thereby preventing lifespan degradation due to exciton accumulation at the interface of the common layer in the phosphorescent stack.

Meanwhile, the light-emitting device according to FIG. 9 includes a phosphorescent stack PS as a blue stack, between the charge generation layers CGL to emit white light.

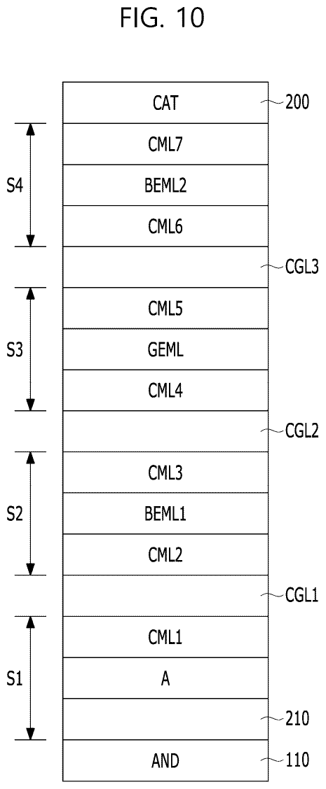

FIG. 10 is a cross-sectional view illustrating a light-emitting device according to a fourth embodiment of the present disclosure.

As shown in FIG. 10, the light-emitting device according to the fourth embodiment of the present disclosure includes four stacks S1, S2, S3, and S4 between the first electrode 110 and the second electrode 200.

The first to fourth stacks S1, S2, S3, and S4 can include charge generation layers CGL1, CGL2, and CGL3 separated between adjacent stacks.

For example, the first stack S1 can include an excess exciton control unit A including the fluorescent material layer 130, the hole transport layer 140, and the red light-emitting layer 150 of FIG. 1. A hole injection layer 210 can be provided below the excess exciton control unit A.

In addition, the second to fourth stacks S2, S3, and S4 can include light-emitting layers BEML1, GEML, and BEML2 of different colors. In addition, hole-transporting common layers CML2, CML4, and CML6 are provided below the different color emitting layers (BEM1, GEML, and BEML2), and common electron transport layers (CML3, CML5, CML7) can be provided on the light-emitting layers (BEM1, GEML, and BEML2) emitting light of different colors.

The example shown in FIG. 10 is an example in which the red stack is adjacent to the first electrode 110, and the light-emitting device of the present disclosure is not limited thereto. When the red stack is not provided in the first stack S1, the red stack is disposed between a charge generation layer and a hole-transport common layer (CML2, CML4, CML6) in any one of the second to fourth stacks S2, S3, and S4, and the light-emitting layer of the corresponding stack can be a red light-emitting layer.

Hereinafter, a light-emitting display device to which the light-emitting device of the present disclosure is applied will be described.

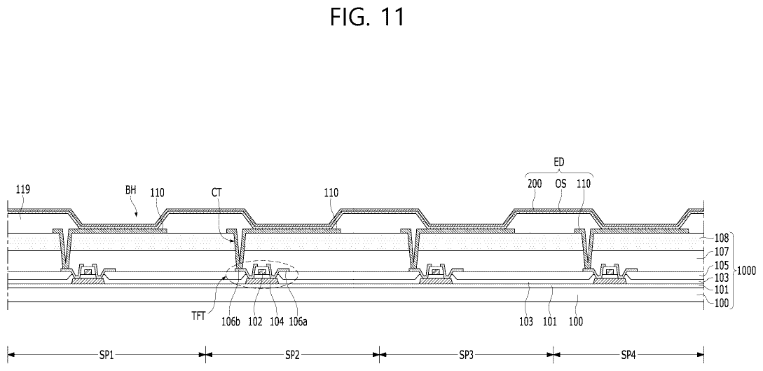

FIG. 11 is a cross-sectional view illustrating the light-emitting display device according to one or more embodiments of the present disclosure.

As shown in FIG. 11, the light-emitting display device according to an embodiment can include the light-emitting device in at least one of a plurality of sub-pixels SP1, SP2, SP3, and SP4.

As shown in FIG. 11, the light-emitting display device of the present disclosure includes a substrate 100 having a plurality of subpixels, a light-emitting device (also referred to as “ED”) commonly provided on the substrate 100, and a thin film transistor TFT provided in each of the subpixels, and connected to the first electrode 110 of the light-emitting device ED.

The thin film transistor TFT includes, for example, a gate electrode 102, a semiconductor layer 104, and a source electrode 106a and a drain electrode 106b connected to respective sides of the semiconductor layer 104. In addition, a channel protection layer can be further provided on the portion where the channel of the semiconductor layer 104 is located in order to prevent direct connection between the source/drain electrodes 106a and 106b and the semiconductor layer 104. The thin film transistor TFT can include a buffer layer 101 on the substrate 100 and can be located on the buffer layer 101.

A gate insulating layer 103 is provided between the gate electrode 102 and the semiconductor layer 104.

The semiconductor layer 104 can be formed of, for example, an oxide semiconductor, amorphous silicon, polycrystalline silicon, or a combination thereof. For example, when the semiconductor layer 104 is an oxide semiconductor, the heating temperature required for forming the thin film transistor can be lowered, and thus the substrate 100 can be freely used and the semiconductor layer 104 is advantageously applied to a flexible display device.

A gate electrode 102 can be provided on the gate insulating film 103, and an interlayer insulating film 105 can be further provided between the gate electrode 102 and the source electrode 106a/drain electrode 106b.

In addition, the drain electrode 106b of the thin film transistor TFT can be connected to the first electrode 110 in a contact hole CT provided in the first and second protective layers 107 and 108.

The first protective layer 107 is provided to primarily protect the thin film transistor TFT, and color filters 109R, 109G, and 109B can be provided on the first protective layer 107.

A second protective layer 108 can be provided on the first protective layer 107 with the color filters 109R, 109G, and 109B.

When the plurality of subpixels includes a red subpixel, a green subpixel, a blue subpixel, and a white subpixel, the device structure described in FIG. 1 or 8 can be applied to the light-emitting device ED in at least the red sub-pixel. In some cases, the light-emitting layer in each sub-pixel can be divided and patterned. A hole transport auxiliary layer can be provided in some of sub-pixels with different light emission colors, and may not be provided in the remainder thereof. In sub-pixels with different emission colors, a hole transport auxiliary layer is further provided to compensate for the optical distance. For example, the hole transport auxiliary layer in a red sub-pixel can be thicker than the hole transport auxiliary layer in a green sub-pixel or a blue sub-pixel.

A second protective layer 108 is positioned under the first electrode 110. The first electrode 110 is formed on the surface of the second protective layer 108 excluding the contact hole CT, is connected to either the drain electrode 106b or the source electrode 106a of the thin film transistor TFT and receives an electrical signal from the thin film transistor TFT.

Here, a configuration including the substrate 100, the thin film transistor TFT, and the first and second protective layers 107 and 108 can be defined as the thin film transistor array substrate 1000.

The light-emitting device ED is formed on the thin film transistor array substrate 1000 including the bank 119 defining the light-emitting portion BH. The light-emitting device ED includes a reflective first electrode 110, a second electrode 200 as a reflective and transparent electrode facing the first electrode 110, and the intermediate layer OS shown in FIG. 1 or 8, between the first and second electrodes 110 and 200. For example, when the red sub-pixel is provided with the light-emitting device ED of FIG. 1 or 8, a hole injection layer HIL, a hole transport layer HTL, an electron blocking layer (EBL), a hole blocking layer HBL, an electron transport layer ETL, an electron injection layer EIL and a charge generation layer CGL and/or an nth common layer CMLn (HTL2, ETL2 . . . ) can be continuously disposed in the remaining sub-pixel. The light-emitting layer in each sub-pixel emits light with a different color, the energy band gap is different depending on the dopant provided for each light-emitting color, and the use of the host and the light-emitting dopant can be different.

The first electrode 110 is divided into respective subpixels, and the remaining layers of the light-emitting device ED excluding the first electrode 110 are integrally provided in the entire display area, regardless of respective subpixels.

Either the first electrode 110 or the second electrode 300 can be connected to a thin film transistor TFT.

A capping layer is provided on the second electrode 200 to improve light emission efficiency and protect the light-emitting device ED.

An encapsulation layer or an encapsulation substrate can be further provided on the second electrode 200 to protect the light-emitting device ED.

Although the illustrated example is shown in consideration of top emission, the embodiments of the present disclosure are not limited thereto.

Meanwhile, in FIG. 11, the intermediate layer OS between the first electrode 110 and the second electrode 200 of the light-emitting device ED can include a plurality of stacks in the sub-pixels S1, S2, S3, and S4 and can have the same configuration, as shown in FIGS. 9 and 10. When a plurality of stacks are provided in a light-emitting device, as shown in FIGS. 9 and 10, the stack emitting red light can have the same configuration and thus have the same effect as in FIG. 1.

In a stack configuration including a phosphorescent red light-emitting layer in the light-emitting display device of the present disclosure described above, it is possible to prevent deterioration of red pure color efficiency due to consumption of non-light-emitting excitons in the fluorescent material layer spaced from the red light-emitting layer with the hole transport layer interposed therebetween, to prevent deterioration in the common layer or the common layer interface due to excitons that diffuse upon excitation of phosphorescence and thereby increase lifespan.

A light-emitting device according to one embodiment of the present disclosure can comprise a first electrode and a second electrode facing each other, a red light-emitting layer between the first electrode and the second electrode and a hole injection layer, a first fluorescent material layer, and a first hole transport layer sequentially provided between the first electrode and the red light-emitting layer. The first fluorescent material layer can have a band gap greater than a band gap of a red dopant contained in the red light-emitting layer.

In a light-emitting device according to one embodiment of the present disclosure, a triplet energy level of the red dopant can be between a triplet energy level of the first hole transport layer and a triplet energy level of the first fluorescent material layer.

In a light-emitting device according to one embodiment of the present disclosure, the first fluorescent material layer can have photoluminescence (PL) at a wavelength shorter than a red wavelength.

In a light-emitting device according to one embodiment of the present disclosure, the first fluorescent material layer may not emit light when the red light-emitting layer emits light.

In a light-emitting device according to one embodiment of the present disclosure, the first fluorescent material layer can be an organic material containing anthracene as a core and the anthracene is substituted with an amine group.

In a light-emitting device according to one embodiment of the present disclosure, the red dopant can be a red phosphorescent material.

In a light-emitting device according to one embodiment of the present disclosure, a total thickness of the first fluorescent material layer and the first hole transport layer can be less than a thickness of the red light-emitting layer and can be equal to or greater than a thickness of the hole injection layer.

In a light-emitting device according to one embodiment of the present disclosure, one surface of the first fluorescent material layer can contact the hole injection layer and the other surface of the first fluorescent material layer can contact the first hole transport layer. A thickness of the first fluorescent material layer can be less than a thickness of the hole injection layer and can be less than or equal to a thickness of the first hole transport layer.

In a light-emitting device according to one embodiment of the present disclosure, the red light-emitting layer can comprise two or more hosts having different band gaps.

A light-emitting device according to one embodiment of the present disclosure can further comprise a charge generation layer and an additional light-emitting layer between the red light-emitting layer and the second electrode, and a second fluorescent material layer and a second hole transport layer between the charge generation layer and the additional light-emitting layer.

A second hole transport contact the additional light-emitting layer, and the second fluorescent material layer can have a band gap greater than a band gap of a light-emitting dopant contained in the additional light-emitting layer.

In a light-emitting device according to one embodiment of the present disclosure, the additional light-emitting layer can emit the same color as the red light-emitting layer.

In a light-emitting device according to one embodiment of the present disclosure, the additional light-emitting layer emits light of color wavelength with a shorter wavelength than the red light-emitting layer.

In a light-emitting device according to one embodiment of the present disclosure, the triplet energy level of the light-emitting dopant in the additional light-emitting layer can fall between the triplet energy level of the second hole transport layer and the triplet energy level of the second fluorescent material layer.

A light-emitting device according to one embodiment of the present disclosure can further comprise an additional light-emitting layer contacting the red light-emitting layer. The additional light-emitting layer can emit light of a color wavelength with a shorter wavelength than the red light-emitting layer.

In a light-emitting device according to one embodiment of the present disclosure, the red dopant and the light-emitting dopant can be phosphorescent dopants.

A light-emitting display device according to one embodiment of the present disclosure can comprise a substrate including a plurality of sub-pixels, a thin film transistor provided in each of the plurality of sub-pixels, a first electrode in at least one of the sub-pixels, the first electrode connected to the thin film transistor, a second electrode facing the first electrode, a red light-emitting layer between the first electrode and the second electrode and a hole injection layer, a first fluorescent material layer, and a first hole transport layer sequentially provided between the first electrode and the red light-emitting layer. The first fluorescent material layer can have a band gap greater than a band gap of a red dopant contained in the red light-emitting layer.

The light-emitting device and the light-emitting display including the same according to the present disclosure have the following effects.

The light-emitting display device of the present disclosure described above prevents deterioration of red pure color efficiency due to consumption of non-light-emitting excitons in the fluorescent material layer spaced from the red light-emitting layer with the hole transport layer interposed therebetween, prevents deterioration in the common layer or the common layer interface due to excitons that diffuse upon excitation of phosphorescence, and thereby increases the lifespan.

In addition, the light-emitting display device of the present disclosure reduces the driving voltage and significantly increasing the lifespan, and greatly contributes to reducing power consumption in a light-emitting device ED that emits white light or a red multiple stack structure.

As a result, the light-emitting display device of the present disclosure reduces greenhouse gases and realizes ESG (environmental/social/governance).

It will be apparent to those skilled in the art that various modifications and variations can be made in the disclosure without departing from the spirit or scope of the disclosure. Thus, it is intended that the disclosure covers such modifications and variations thereof, provided they fall within the scope of the appended claims and their equivalents.

What is claimed is:

1. A light-emitting device comprising:
a first electrode and a second electrode facing each other;
a red light-emitting layer between the first electrode and the second electrode; and
a hole injection layer, a first fluorescent material layer, and a first hole transport layer sequentially provided between the first electrode and the red light-emitting layer,
wherein the first fluorescent material layer has a band gap greater than a band gap of a red dopant contained in the red light-emitting layer.

2. The light-emitting device according to claim 1, wherein a triplet energy level of the red dopant contained in the red light-emitting layer is between a triplet energy level of the first hole transport layer and a triplet energy level of the first fluorescent material layer.

3. The light-emitting device according to claim 1, wherein the first fluorescent material layer has photoluminescence (PL) at a wavelength shorter than a red wavelength.

4. The light-emitting device according to claim 1, wherein the first fluorescent material layer does not emit light when the red light-emitting layer emits light.

5. The light-emitting device according to claim 1, wherein the first fluorescent material layer includes an organic material containing anthracene as a core, and the anthracene is substituted with an amine group.

6. The light-emitting device according to claim 1, wherein the red dopant contained in the red light-emitting layer includes a red phosphorescent material.

7. The light-emitting device according to claim 1, wherein a total thickness of the first fluorescent material layer and the first hole transport layer is less than a thickness of the red light-emitting layer, and is equal to or greater than a thickness of the hole injection layer.

8. The light-emitting device according to claim 1, wherein one surface of the first fluorescent material layer contacts the hole injection layer, and another surface of the first fluorescent material layer contacts the first hole transport layer, and
wherein a thickness of the first fluorescent material layer is less than a thickness of the hole injection layer and is less than or equal to a thickness of the first hole transport layer.

9. The light-emitting device according to claim 1, wherein the red light-emitting layer comprises two or more hosts having different band gaps.

10. The light-emitting device according to claim 1, further comprising:
a charge generation layer and an additional light-emitting layer between the red light-emitting layer and the second electrode; and
a second fluorescent material layer and a second hole transport layer between the charge generation layer and the additional light-emitting layer,
wherein a second hole transport layer contacts the additional light-emitting layer, and
wherein the second fluorescent material layer has a band gap greater than a band gap of a light-emitting dopant contained in the additional light-emitting layer.

11. The light-emitting device according to claim 10, wherein the additional light-emitting layer emits a same color as the red light-emitting layer.

12. The light-emitting device according to claim 10, wherein the additional light-emitting layer emits light having a color wavelength that is shorter than the red light-emitting layer.

13. The light-emitting device according to claim 10, wherein the triplet energy level of the light-emitting dopant in the additional light-emitting layer falls between the triplet energy level of the second hole transport layer and the triplet energy level of the second fluorescent material layer.

14. The light-emitting device according to claim 1, further comprising an additional light-emitting layer contacting the red light-emitting layer,
wherein the additional light-emitting layer emits light having a color wavelength that is shorter than the red light-emitting layer.

15. The light-emitting device according to claim 14, wherein the red dopant and a light-emitting dopant in the additional light-emitting layer are phosphorescent dopants.

16. A light-emitting display device comprising:
a substrate including a plurality of sub-pixels;
a thin film transistor provided in each of the plurality of sub-pixels;
a first electrode in at least one of the plurality of sub-pixels, the electrode connected to the thin film transistor;
a second electrode facing the first electrode;
a red light-emitting layer between the first electrode and the second electrode; and
a hole injection layer, a first fluorescent material layer, and a first hole transport layer sequentially provided between the first electrode and the red light-emitting layer,
wherein the first fluorescent material layer has a band gap greater than a band gap of a red dopant contained in the red light-emitting layer.

17. The light-emitting display device according to claim 16, wherein a triplet energy level of the red dopant contained in the red light-emitting layer is between a triplet energy level of the first hole transport layer and a triplet energy level of the first fluorescent material layer.

18. The light-emitting display device according to claim 16, wherein the first fluorescent material layer has photoluminescence (PL) at a wavelength shorter than a red wavelength.

19. The light-emitting display device according to claim 16, wherein the first fluorescent material layer does not emit light when the red light-emitting layer emits light.

20. The light-emitting display device according to claim 16, wherein the first fluorescent material layer includes an organic material containing anthracene as a core, and the anthracene is substituted with an amine group.

21. The light-emitting display device according to claim 16, wherein the red dopant contained in the red light-emitting layer includes a red phosphorescent material.
